(19) United States
(12) Patent Application Publication
(10) Pub. No.: US 2024/0324314 A1
(43) Pub. Date: Sep. 26, 2024

(54) DISPLAY APPARATUS

(71) Applicant: Samsung Display Co., Ltd., Yongin-si (KR)

(72) Inventors: Gwangmin Cha, Yongin-si (KR); Jungi Kim, Yongin-si (KR); Hyesun Kim, Yongin-si (KR); Sanghyun Yun, Yongin-si (KR)

(21) Appl. No.: 18/611,448

(22) Filed: Mar. 20, 2024

(30) Foreign Application Priority Data
Mar. 24, 2023 (KR) 10-2023-0039119
Jul. 14, 2023 (KR) 10-2023-0092030

(51) Int. Cl. H10K 59/122; G09G 3/32

(52) U.S. Cl. CPC H10K 59/122; G09G 3/32; G09G 2300/0421; G09G 2300/0842

(57) ABSTRACT

A display apparatus includes: a substrate; a pixel-circuit layer including a pixel circuit; a via insulating layer on the pixel-circuit layer; a first electrode on the via insulating layer; a pixel-defining layer on the first electrode and exposing a portion of the first electrode; and a second electrode on the first electrode. The pixel-defining layer includes: first pixel-defining layers extending in a first direction and adjacent to each other in a second direction crossing the first direction; and second pixel-defining layers respectively between adjacent ones of the first pixel-defining layers. The second pixel-defining layers are spaced apart from each other, and the via insulating layer has a groove in at least a portion of a region at where the first pixel-defining layers overlaps the via insulating layer.

### CROSS-REFERENCE TO RELATED APPLICATIONS

The present application claims priority to and the benefit of Korean Patent Application Nos. 10-2023-0039119, filed in the Korean Intellectual Property Office on Mar. 24, 2023, and 10-2023-0092030, filed in the Korean Intellectual Property Office on Jul. 14, 2023, the entire disclosure of both of which are incorporated herein by reference.

### BACKGROUND

### 1. Field

Aspects of embodiments relate to a display apparatus.

### 2. Description of the Related Art

A display apparatus visually displays data. With the development of various electronic apparatuses, such as mobile phones, personal digital assistants (PDAs), large-scale televisions, and the like, various types of display apparatuses applicable thereto have been developed. As an example, widely used display apparatuses include a liquid crystal display apparatus having a backlight unit and an organic light-emitting display apparatus that emits light of different colors for each region. Recently, a display apparatus having a quantum dot-color conversion layer (QD-CCL) has been developed.

A display apparatus includes a thin-film transistor and light-emitting diodes including an emission layer and operates when the light-emitting diodes emit light. The emission layer may be formed by using various suitable methods and may be formed by using, for example, an inkjet process and the like.

### SUMMARY

In a conventional display apparatus in which an emission layer is formed by using an inkjet process, pixel-defining layers near the emission layer may be formed to have a repellent (e.g., hydrophobic) characteristic. As an example, a line-shaped repellent pixel-defining layer may be disposed on a line-shaped hydrophilic pixel-defining layer to cross each other. However, when a repellent pixel-defining layer is formed to cross a hydrophilic pixel-defining layer, the thickness of a portion of the repellent pixel-defining layer that crosses the hydrophilic pixel-defining layer is less than the thickness of a portion of the repellent pixel-defining layer that does not cross the hydrophilic pixel-defining layer. Accordingly, a repellent characteristic of the pixel-defining layer is relatively reduced.

Embodiments of the present disclosure include a display apparatus exhibiting improved reliability by reducing a loss in a repellent characteristic of a pixel-defining layer. However, these aspects and features are just examples, and the present disclosure is not limited thereto.

Additional aspects and features will be set forth, in part, in the description that follows and, in part, will be apparent from the description or may be learned by practice of the described embodiments.

According to an embodiment of the present disclosure, a display apparatus includes: a substrate; a pixel-circuit layer on the substrate and including a pixel circuit; a via insulating layer on the pixel-circuit layer; a first electrode on the via insulating layer; a pixel-defining layer on the first electrode and exposing a portion of the first electrode; and a second electrode on the first electrode. The pixel-defining layer includes: a plurality of first pixel-defining layers extending in a first direction and adjacent to each other in a second direction crossing the first direction; and a plurality of second pixel-defining layers respectively between adjacent ones of the first pixel-defining layers. The second pixel-defining layers are spaced apart from each other, and the via insulating layer has a groove in at least a portion of a region at where the first pixel-defining layers overlaps the via insulating layer.

The first pixel-defining layers may have a repellent characteristic, and the second pixel-defining layers may have a hydrophilic characteristic.

The first electrode may be provided in plurality, each of the first pixel-defining layers may have a first portion between the first electrodes and a second portion outside the first portion and between adjacent ones of the second pixel-defining layers, and the groove in the via insulating layer may overlap the second portion of each of the first pixel-defining layers.

The groove in the via insulating layer may extend in the first direction and may overlap the first portion and the second portion of each of the first pixel-defining layers.

At least a portion of the second portion of each of the first pixel-defining layers may not overlap the second pixel-defining layers.

A thickness of each of the first pixel-defining layers may be greater than a thickness of each of the second pixel-defining layers.

A width of the first pixel-defining layer in the second direction between an adjacent pair of the second pixel-defining layers from among the first pixel-defining layers may be equal to a distance between the adjacent pair of second pixel-defining layers.

A width of the first pixel-defining layer in the second direction between an adjacent pair of the second pixel-defining layers from among the first pixel-defining layers may be greater than a distance between the adjacent pair of second pixel-defining layers.

The first electrode may be provided in plurality, and the pixel-defining layer and the first electrodes may cover an entire upper surface of the via insulating layer.

The groove in the via insulating layer may not overlap the first electrode.

According to another embodiment of the present disclosure, a display apparatus includes: a substrate; a pixel-circuit layer on the substrate and including a pixel circuit; a first electrode on the pixel-circuit layer; a pixel-defining layer on the first electrode and exposing a portion of the first electrode; and a second electrode on the first electrode. The pixel-defining layer includes: a plurality of first pixel-defining layers extending in a first direction and adjacent to each other in a second direction crossing the first direction; and a plurality of second pixel-defining layers respectively between adjacent ones of the first pixel-defining layers. The second pixel-defining layers are spaced apart from each other, and a width of the first pixel-defining layer in the second direction between an adjacent pair of second pixel-defining layers from among the first pixel-defining layers is equal to or greater than a distance between the adjacent pair of second pixel-defining layers.

The first pixel-defining layers may include a repellent material, and the second pixel-defining layers may include a hydrophilic material.

The first pixel-defining layers may each have a uniform thickness in the first direction.

The first electrode may be provided in plurality, each of the first pixel-defining layers may have a first portion between adjacent ones of the first electrodes and a second portion outside the first portion and between adjacent ones of the second pixel-defining layers, and a thickness of the second portion of each of the first pixel-defining layers may be greater than a thickness of the first portion.

The display apparatus may further include a via insulating layer between the pixel-circuit layer and the first electrode, and the via insulating layer may have grooves in at least a portion of a region overlapping the first pixel-defining layers.

The grooves may extend in the first direction and may be adjacent to each other in the second direction.

The first electrode may be provided in plurality, each of the first pixel-defining layers may have a first portion arranged between adjacent ones of the first electrodes and a second portion arranged outside the first portion and arranged between adjacent ones of the second pixel-defining layers, and the grooves may overlap the second portion of the second pixel-defining layers.

The grooves in the via insulating layer may not overlap the first electrode.

A thickness of each of the first pixel-defining layers may be equal to or greater than a thickness of each of the second pixel-defining layers.

The first electrode may be provided in plurality, each of the first pixel-defining layers may have a first portion between adjacent ones of the first electrodes and a second portion outside the first portion and between adjacent ones of the second pixel-defining layers, and at least a portion of the second portion of each of the first pixel-defining layers may not overlap the second pixel-defining layers.

### BRIEF DESCRIPTION OF THE DRAWINGS

The above and other aspects and features of embodiments of the present disclosure will be more apparent from the following description taken in conjunction with the accompanying drawings, in which:

FIG. 1 is a schematic perspective view of a display apparatus according to an embodiment;

FIG. 2 is an equivalent circuit diagram of a pixel circuit of a display apparatus according to an embodiment;

FIGS. 3 and 4 are schematic plan views of a portion of a display area of a display apparatus according to an embodiment;

FIGS. 5 to 7 are schematic cross-sectional views of the display apparatus shown in FIG. 3;

FIG. 8 is a schematic plan view of a portion of a display area of a display apparatus according to another embodiment;

FIGS. 9 to 11 are schematic cross-sectional views of the display apparatus shown in FIG. 8;

FIG. 12 is a schematic plan view of a portion of a display area of a display apparatus according to another embodiment;

FIGS. 13 to 15 are schematic cross-sectional views of the display apparatus shown in FIG. 12;

FIG. 16 is a schematic plan view of a pixel-defining layer in a display area of a display apparatus according to another embodiment; and

FIG. 17 is a schematic cross-sectional view of the display apparatus shown in FIG. 16.

### DETAILED DESCRIPTION

Reference will now be made, in detail, to embodiments, examples of which are illustrated in the accompanying drawings. In this regard, the described embodiments may have different forms and should not be construed as being limited to the descriptions set forth herein. Accordingly, embodiments are merely described below, by referring to the figures, to explain aspects and features of the present description.

As the disclosure allows for various changes and numerous embodiments, some embodiments will be illustrated in the drawings and described in the written description. Aspects and features of the present disclosure, and methods for achieving them, will be clarified with reference to the embodiments described below in detail with reference to the drawings. However, the present disclosure is not limited to the following embodiments and may be embodied in various forms.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

The x-axis, y-axis, and z-axis are not limited to three axes of the rectangular coordinate system and may be interpreted in a broader sense. For example, the x-axis, y-axis, and z-axis may be perpendicular to one another or may represent different directions that are not perpendicular to one another.

Hereinafter, embodiments of the present disclosure will be described with reference to the accompanying drawings,

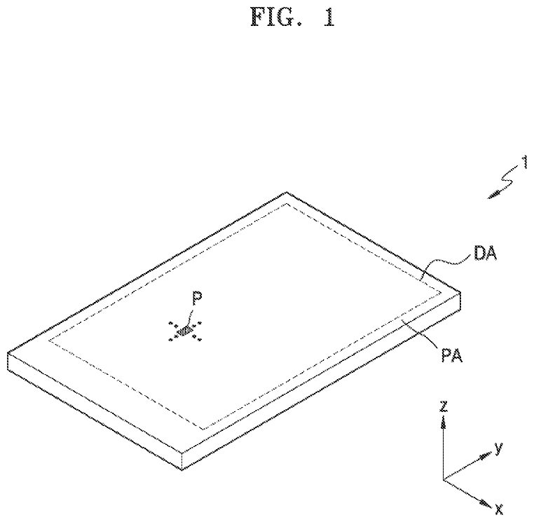

FIG. 1 is a schematic perspective view of a display apparatus 1 according to an embodiment.

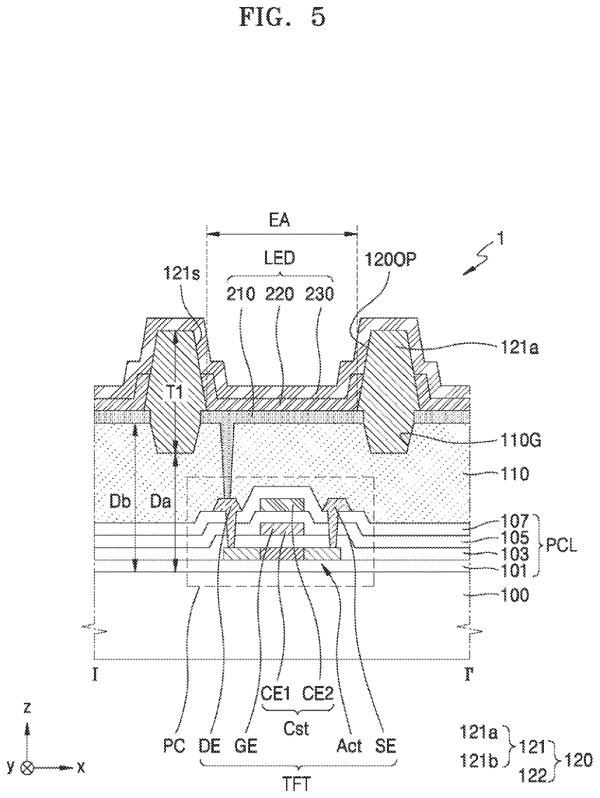

Referring to FIG. 1, the display apparatus 1 may have a display area DA and a peripheral area PA. A plurality of pixels P are arranged in the display area DA, and the peripheral area PA is outside the display area DA. For example, the peripheral area PA may surround (e.g., may extend around a periphery of) the display area DA entirely. This may be understood that a substrate 100 (see, e.g., FIG. 5) included in the display apparatus has (or defines) the display area DA and the peripheral area PA.

Each pixel P of the display apparatus 1 is a region that may be configured to emit light of a preset color. The display apparatus 1 may be configured to display images by using light from the pixels P. As an example, each pixel P may be configured to emit red light, green light, or blue light.

As shown in FIG. 1, the display area DA may have a polygonal shape, such as a quadrangular shape. As an example, the display area DA may have a rectangular shape in which a horizontal length thereof is greater than a vertical length thereof, a rectangular shape in which a horizontal length thereof is less than a vertical length thereof, or a square shape. In other embodiments, the display area DA may have various shapes, such as an elliptical shape or a circular shape.

The peripheral area PA may be a non-display area in which the pixels P are not arranged. A driver and the like configured to provide electric signals or power to the pixels P may be disposed in the peripheral area PA. Pads may be disposed in the peripheral area PA, and various kinds of electronic elements or a printed circuit board may be electrically connected to the pads. The pads may be spaced apart from each other in the peripheral area PA and electrically connected to the printed circuit board or an integrated circuit element.

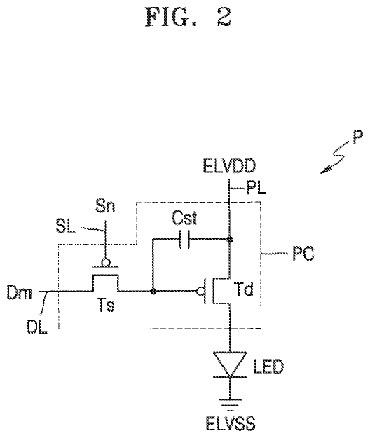

FIG. 2 is an equivalent circuit diagram of a pixel circuit PC of the display apparatus 1 according to an embodiment. The pixel circuit PC may be electrically connected to a light-emitting diode LED, and one light-emitting diode LED may correspond to one pixel P.

The pixel circuit PC may include a first transistor Td, a second transistor Ts, and a storage capacitor Cst.

The second transistor Ts is a switching thin-film transistor, may be connected to a scan line SL and a data line DL, and may be configured to be turned on according to a switching signal input from the scan line SL to transfer a data signal input from the data line DL to the first transistor Td. The storage capacitor Cst has one end electrically connected to the second transistor Ts and another end electrically connected to a driving voltage line PL. The storage capacitor Cst may be configured to store a voltage corresponding to a difference between a voltage transferred from the second transistor Ts and a driving power voltage ELVDD supplied to the driving voltage line PL.

The first transistor Td is a driving transistor, may be connected to the driving voltage line PL and the storage capacitor Cst, and may be configured to control the magnitude of a driving current flowing from the driving voltage line PL to the light-emitting diode LED according to the voltage stored in the storage capacitor Cst. The light-emitting diode LED may be configured to emit light having a brightness (e.g., a preset brightness) corresponding to the driving current. An opposite electrode of the light-emitting diode LED may be configured to receive an electrode power voltage ELVSS.

Although it is described with reference to FIG. 2 that the pixel circuit PC includes two thin-film transistors and one storage capacitor, the present disclosure is not limited thereto. In another embodiment, the pixel circuit PC may include seven thin-film transistors and one storage capacitor. In some embodiments, the pixel circuit PC may include two or more storage capacitors.

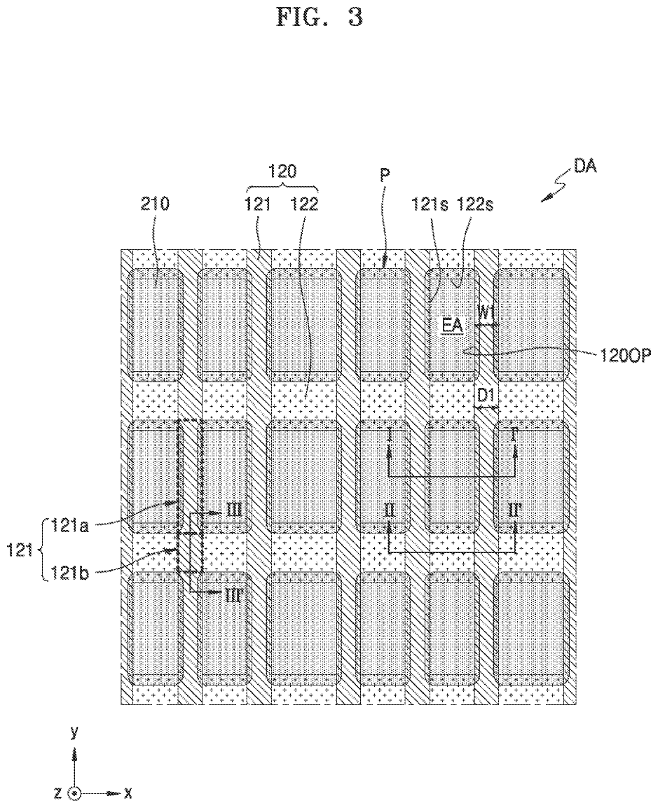

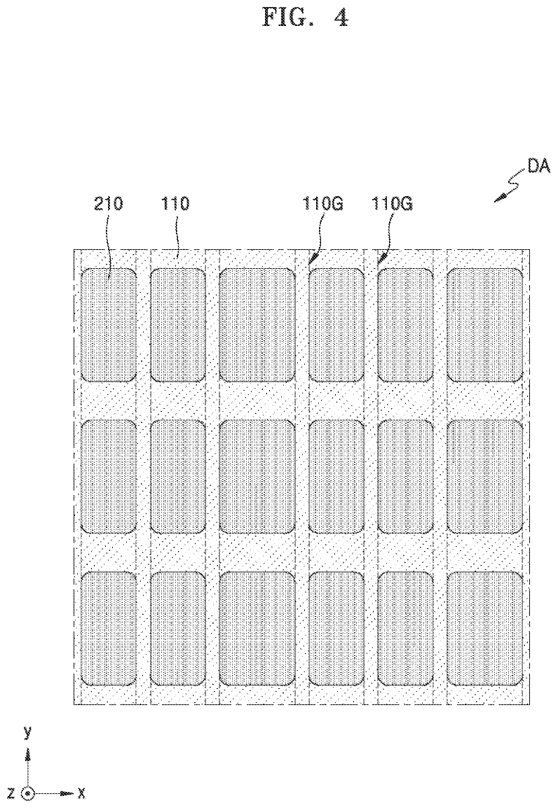

FIGS. 3 and 4 are schematic plan views of a portion of the display area DA of a display apparatus according to an embodiment. FIG. 3 shows a plan view of a first pixel-defining layer 121, and FIG. 4 shows a plan view of a via insulating layer 110 in a region corresponding to that shown in FIG. 3.

Referring to FIGS. 3 and 4, the display apparatus may include a plurality of pixels P arranged in the display area DA. Each of the pixels P may denote a sub-pixel and may include a display element, such as a light-emitting diode OLED. The pixel P may be configured to emit, for example, red, green, or blue light.

Each pixel P may include a first electrode 210. The first electrode 210 may be provided in plurality in the display area DA. The first electrodes 210 may be spaced apart from each other in a plan view. The first electrodes 210 may have the same size or different sizes.

The pixel-defining layer 120 may be disposed on the first electrode 210. The pixel-defining layer 120 may have an opening 120OP exposing at least a portion of the first electrode 210. The pixel-defining layer 120 may cover edges of the first electrode 210. The opening 120OP in the pixel-defining layer 120 may expose the central portion of the first electrode 210. Emission layers 220 (see, e.g., FIG. 5) configured to emit light may be disposed in the opening 120OP in the pixel-defining layer 120. A second electrode 230 (see, e.g., FIG. 5) described below may be disposed on the emission layers. A stack structure of the first electrode 210, the emission layer 220, and the second electrode 230 may form one light-emitting diode LED. One opening 120OP in the pixel-defining layer 120 may correspond to one light-emitting diode LED and may define one emission area EA.

The pixel-defining layer 120 may include a plurality of first pixel-defining layers 121 and a plurality of second pixel-defining layers 122.

The first pixel-defining layers 121 may each extend in a first direction (e.g., a y direction). The first pixel-defining layers 121 may be arranged in (e.g., may be adjacent to each other in) a second direction (e.g., an x direction) crossing the first direction. That is, the first pixel-defining layers 121 may be spaced apart from each other in the second direction. The first pixel-defining layer 121 may have a line shape. The first pixel-defining layer 121 may cover a portion of the first electrode 210.

The second pixel-defining layers 122 may be disposed between adjacent ones of the first pixel-defining layers 121. Each of the second pixel-defining layers 122 may be disposed between a pair of adjacent first pixel-defining layers 121 from among the first pixel-defining layers 121. The second pixel-defining layers 122 may be spaced apart from each other in the first direction (e.g., the y direction) and the second direction (e.g., the x direction).

The second pixel-defining layers 122 may be spaced apart from each other by the first pixel-defining layer 121. The second pixel-defining layers 122 may be formed to have an island pattern. The second pixel-defining layers 122 may cover a portion of the first electrode 210.

The opening 120OP in the pixel-defining layer 120 may be defined by lateral surfaces 121s of a pair of first pixel-defining layers 121 adjacent to each other and lateral surfaces 122s of a pair of second pixel-defining layers 122 adjacent to each other. A pair of first pixel-defining layers 121 adjacent to each other and a pair of second pixel-defining layers 122 adjacent to each other may expose a portion of (e.g., a central portion of) the first electrode 210. For example, each of the first pixel-defining layers 121 may cover a portion of the first electrode 210 and may not overlap the remaining portion of the first electrode 210.

A width W1 of the first pixel-defining layer 121 in the second direction (e.g., the x direction) disposed between a pair of second pixel-defining layers 122 adjacent to each other in the second direction (e.g., the x direction) from among the first pixel-defining layers 121 may be substantially equal to a distance D1 between a pair of second pixel-defining layers 122 adjacent to each other. However, the present disclosure is not limited thereto. The width W1 of the first pixel-defining layer 121 may be defined as a maximum width of the first pixel-defining layer 121. The distance D1 between the second pixel-defining layers 122 may be defined as a distance between lower surfaces of the second pixel-defining layers 122. In an embodiment, the first pixel-defining layer 121 may not overlap the second pixel-defining layer 122. In other words, the first pixel-defining layer 121 may not cover the upper surface of the second pixel-defining layer 122.

The first pixel-defining layer 121 may have a first portion 121a disposed between the first electrodes 210 and a second portion 121b disposed outside the first portion 121a. The first portion 121a of the first pixel-defining layer 121 may overlap a portion of the first electrode 210, and the second portion 121b of the first pixel-defining layer 121 may not overlap the first electrode 210. The second portion 121b of the first pixel-defining layer 121 may be disposed between the second pixel-defining layers 122. For example, the second portion 121b of the first pixel-defining layer 121 may be disposed between portions of the second pixel-defining layers 122 that do not overlap (e.g., are offset from) the first electrode 210. A portion of the first pixel-defining layer 121 may overlap a portion of the edge of the second pixel-defining layer 122. The first portion 121a and the second portion 121b of the first pixel-defining layer 121 may each have a plurality of portions repeatedly disposed in the first direction (e.g., the y direction).

At least a portion of the second portion 121b of the first pixel-defining layer 121 may not overlap the second pixel-defining layer 122. In an embodiment, all of the second portions 121b of the first pixel-defining layer 121 may not overlap the second pixel-defining layer 122.

The first pixel-defining layers 121 may have a repellent (e.g., hydrophobic) characteristic, and the second pixel-defining layers 122 may have a hydrophilic characteristic. In the present specification, a repellent characteristic indicates that a contact angle with respect to a solvent in an ink including a light-emitting material forming the emission layer 220 (see, e.g., FIG. 5), or a contact angle of a light-emitting material with respect to ink including the light-emitting material, is relatively large during an inkjet process. As an example, having a repellent characteristic indicates that a contact angle with respect to a solvent in an ink including a light-emitting material forming the emission layer 220, or a contact angle of a light-emitting material with respect to ink including the light-emitting material, is about 90° during an inkjet process. In addition, having a hydrophilic characteristic indicates that a contact angle with respect to a solvent in an ink including a light-emitting material forming the emission layer of the intermediate layer 220, or a contact angle of a light-emitting material with respect to ink including the light-emitting material, is relatively small during an inkjet process.

The first pixel-defining layers 121 may include a fluorine-based component. In an embodiment, the first pixel-defining layer 121 may include a fluorine resin. As an example, the first pixel-defining layers 121 may include an organic material having an unsaturated bond and a fluoro group. In other embodiments, the first pixel-defining layers 121 may include an organic material having an unsaturated bond and fluorine. A fluoro group or fluorine included in the first pixel-defining layers 121 may improve a repellant characteristic of the surface of the first pixel-defining layers 121. The second pixel-defining layers 122 may include an organic material. As an example, the second pixel-defining layers 122 may include an organic material, such as polyimide or hexamethyldisiloxane (HMDSO).

As shown in FIG. 4, the first electrodes 210 may be disposed on the via insulating layer 110. The via insulating layer 110 may be disposed under the first electrodes 210. Referring to FIGS. 3 and 4 together, the first electrodes 210 and the pixel-defining layer 120 may be disposed on the via insulating layer 110. The first electrodes 210 and the pixel-defining layer 120 may together cover the entire upper surface of the via insulating layer 110.

The via insulating layer 110 may have a groove 110G. In the present specification, the groove 110G in the via insulating layer 110 may be a region in which a height of the upper surface of the via insulating layer 110 is relatively low. As an example, a distance between the upper surface of the substrate 100 and the uppermost surface of the via insulating layer 110 may be greater than a distance between the upper surface of the substrate 100 and the upper surface of the via insulating layer 110 at where the groove 110G is located. The groove 110G in the via insulating layer 110 may be formed by removing a portion of the via insulating layer 110.

The via insulating layer 110 may have the groove 110G in at least a portion thereof overlapping the first pixel-defining layers 121. The via insulating layer 110 may have a plurality of grooves 110G overlapping each of the first pixel-defining layers 121. In an embodiment, each of the grooves 110G in the via insulating layer 110 may be formed in a line similar to the first pixel-defining layer 121. As an example, the grooves 110G in the via insulating layer 110 may extend in the first direction (e.g., the y direction) and may be arranged in (e.g., may be adjacent to each other in) the second direction (e.g., the x direction) as shown in FIG. 4. As an example, the groove 110G in the via insulating layer 110 may overlap the first portion 121a and the second portion 121b of the first pixel-defining layer 121.

The groove 110G in the via insulating layer 110 may not overlap the first electrodes 210. For example, a distance between the first electrodes 210 adjacent to each other in the second direction (e.g., the x direction) may be substantially equal to or greater than the width of the groove 110G in the via insulating layer 110 in the second direction.

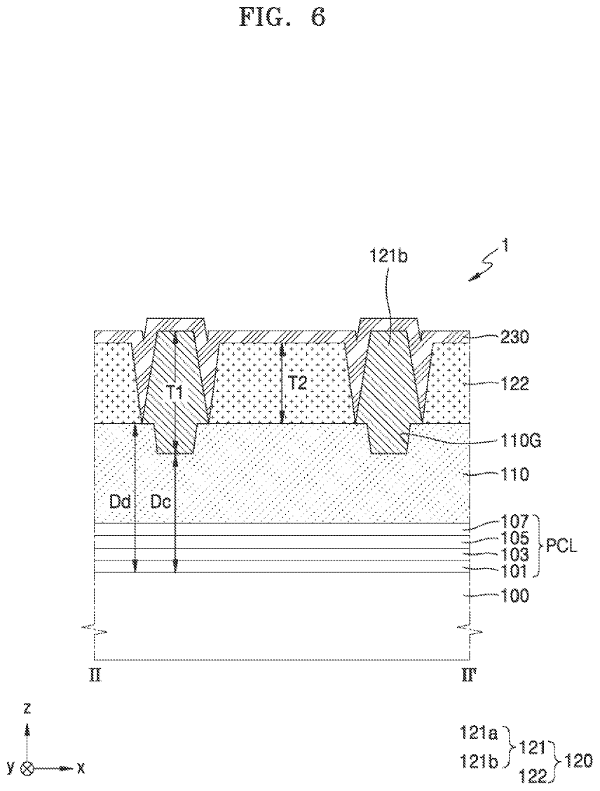

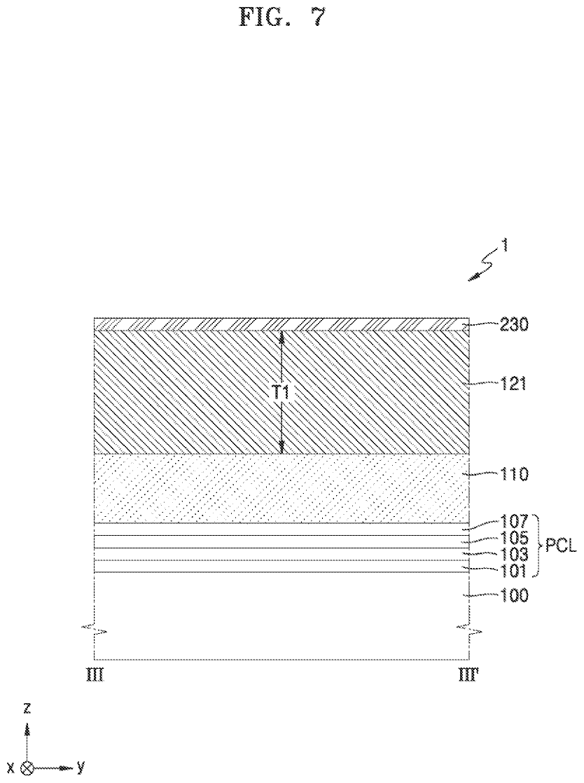

FIGS. 5 to 7 are schematic cross-sectional views of the display apparatus shown in FIGS. 3 and 4. FIG. 5 is a schematic cross-sectional view of the display apparatus shown in FIG. 3 taken along the line I-I′ in FIG. 3. FIG. 6 is a schematic cross-sectional view of the display apparatus shown in FIG. 3 taken along the line II-II′ in FIG. 3. FIG. 7 is a schematic cross-sectional view of the display apparatus shown in FIG. 3 taken along the line III-III′ in FIG. 3.

Referring to FIGS. 5 to 7, the display apparatus 1 may include a light-emitting diode LED in the display area. The light-emitting diode LED may be electrically connected to a pixel circuit PC disposed between the substrate 100 and the light-emitting diode LED in a direction (e.g., a z direction) perpendicular to (or normal to) the substrate 100.

The display apparatus 1 may include the substrate 100, a pixel-circuit layer PCL on the substrate 100, the via insulating layer 110 on the pixel-circuit layer PCL, the pixel-defining layer 120 on the via insulating layer 110, and the light-emitting diode LED on the via insulating layer 110.

The substrate 100 may include glass or a polymer resin. The polymer resin may include a polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose acetate propionate (CAP), and the like. The substrate 100 including the polymer resin may be flexible, rollable, or bendable. The substrate 100 may have a multi-layered structure including a layer that includes the polymer resin and an inorganic layer.

The pixel-circuit layer PCL may include a buffer layer 101, a first insulating layer 103, a second insulating layer 105, a third insulating layer 107, and a thin-film transistor TFT.

The buffer layer 101 may be disposed on the substrate 100 to planarize an upper surface of the substrate 100 and to block impurities from entering through the substrate 100. The buffer layer 101 may include an inorganic insulating material, such as silicon oxide (SiO_{X}), silicon nitride (SiN_{X}), and silicon oxynitride (SiO_{X}N_{Y}). The buffer layer 101 may be a single-layered or multi-layered structure including the inorganic insulating material.

The pixel circuit PC may include at least one thin-film transistor TFT and a storage capacitor Cst. The thin-film transistor TFT may include a semiconductor layer Act, a gate electrode GE, a source electrode SE, and a drain electrode DE.

The semiconductor layer Act may be disposed on the buffer layer 101. The semiconductor layer Act may include an oxide semiconductor and/or a silicon semiconductor. In an embodiment in which the semiconductor layer Act includes an oxide semiconductor, the semiconductor layer Act may include, for example, an oxide of at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn). As an example, the semiconductor layer Act may be an ITZO (InSnZnO) semiconductor layer, an IGZO (InGaZnO) semiconductor layer, and the like. In an embodiment in which the semiconductor layer Act includes a silicon semiconductor, the semiconductor layer Act may include, for example, amorphous silicon or low-temperature polycrystalline silicon (LTPS).

The gate electrode GE may be disposed over the semiconductor layer Act with the first insulating layer 103 therebetween. The gate electrode GE may overlap a channel region of the semiconductor layer Act. The gate electrode GE may include a low-resistance metal material. As an example, the gate electrode GE may include at least one metal from among aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may be a single layer or a multi-layer including the above metals. The gate electrode GE may be connected to a gate line configured to apply electrical signals to the gate electrode GE.

The first insulating layer 103 may be disposed on the buffer layer 101. The first insulating layer 103 may be disposed between the semiconductor layer Act and the gate electrode GE. The first insulating layer 103 may include, for example, an inorganic insulating material, such as silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (ZnO).

The second insulating layer 105 may be disposed on the first insulating layer 103. The second insulating layer 105 may cover the second electrode GE. Similar to the first insulating layer 103, the second insulating layer 105 may include an inorganic insulating material including silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (ZnO).

An upper electrode CE2 of the storage capacitor Cst may be disposed on the second insulating layer 105. In an embodiment, the upper electrode CE2 may overlap the gate electrode GE. In such an embodiment, the gate electrode GE and the upper gate electrode CE2 overlapping each other with the second insulating layer 105 therebetween may constitute (or may form) the storage capacitor Cst. That is, the gate electrode GE may act as a lower electrode CE1 of the storage capacitor Cst. The storage capacitor Cst and the thin-film transistor TFT may overlap each other. In another embodiment, the storage capacitor Cst and the thin-film transistor TFT may not overlap each other.

The third insulating layer 107 may be disposed on the second insulating layer 105. The third insulating layer 107 may cover the upper electrode CE2. The third insulating layer 107 may include silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (ZnO). The third insulating layer 107 may be a single layer or a multi-layer including the inorganic insulating material.

The source electrode SE and the drain electrode DE may be disposed on the third insulating layer 107. The source electrode SE and the drain electrode DE may each be electrically connected to the semiconductor layer Act through a contact hole (e.g., a contact opening) formed in the first insulating layer 103, the second insulating layer 105, and the third insulating layer 107. The source electrode SE and the drain electrode DE may each include a material having high conductivity. At least one of the source electrode SE and the drain electrode DE may include a conductive material including molybdenum (Mo), aluminum (Al), copper (Cu), and titanium (Ti) and may be a single layer or a multi-layer including the above materials. In an embodiment, at least one of the source electrode SE and the drain electrode DE may have a multi-layered structure of Ti/Al/Ti.

The via insulating layer 110 may be disposed on the third insulating layer 107. The via insulating layer 110 may be disposed on the source electrode SE and the drain electrode DE. Although the via insulating layer 110 is shown as being a single layer, the present disclosure is not limited thereto, and the via insulating layer 110 may be a multi-layer structure.

In an embodiment, the via insulating layer 110 may have the groove 110G in an region entirely overlapping the first pixel-defining layer 121. In an embodiment, the via insulating layer 110 may have the groove 110G in a region overlapping the first portion 121a and the second portion 121b of the first pixel-defining layer 121.

The via insulating layer 110 may include an organic insulating layer including an organic material. The via insulating layer 110 may include an organic insulating material including a general-purpose polymer, such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. The via insulating layer 110 may planarize an upper surface of the pixel circuit PC to planarize a surface on which the light-emitting diode LED is disposed.

The light-emitting diode LED may be disposed on the via insulating layer 110. The light-emitting diode LED may be configured to emit, for example, red, green, or blue light or to emit red, green, blue, or white light.

The light-emitting diode LED may include an organic light-emitting diode including an organic emission layer. In another embodiment, the light-emitting diode LED may be an inorganic light-emitting diode including an inorganic emission layer. The size of the light-emitting diode may be on a microscale or nanoscale. As an example, the light-emitting diode may be a micro light-emitting diode. In another embodiment, the light-emitting diode may be a nanorod light-emitting diode. The nanorod light-emitting diode may include gallium nitride (GaN). In an embodiment, a color-converting layer may be disposed on the nano-rod light-emitting diode. The color-converting layer may include quantum dots. In another embodiment, the light-emitting diode may be a quantum-dot light-emitting diode including a quantum-dot emission layer.

The light-emitting diode LED may include the first electrode 210, an intermediate layer 220, and the second electrode 230. Although the first electrode 210 of the light-emitting diode LED may be an anode and the second electrode 230 may be a cathode, the present disclosure is not limited thereto. As an example, the light-emitting diode LED may be an inverted light-emitting diode in which the first electrode 210 is a cathode and the second electrode 230 is an anode. Hereinafter, for convenience of description, an embodiment in which the first electrode 210 is an anode and the second electrode 230 is a cathode is described.

The first electrode 210 may be disposed on the via insulating layer 110. The first electrode 210 may be electrically connected to the thin-film transistor TFT. As an example, the first electrode 210 may be electrically connected to the thin-film transistor TFT through a contact hole (e.g., a contact opening) in the via insulating layer 110.

The first electrode 210 may include a conductive oxide, such as indium tin oxide (ITO), indium zinc oxide (IZO), zinc oxide (ZnO), indium oxide (e.g., In₂O₃), indium gallium oxide (IGO), or aluminum zinc oxide (AZO). In another embodiment, the first electrode 210 may include a reflective layer including silver (Ag), magnesium (Mg), aluminum (AI), platinum (Pt), palladium (Pd), gold (Au), nickel (Ni), neodymium (Nd), iridium (Ir), chrome (Cr), or a compound thereof. In another embodiment, the first electrode 210 may further include a layer on or under the reflective layer including ITO, IZO, ZnO, or In₂O₃.

The pixel-defining layer 120 may be disposed on the first electrode 210. The pixel-defining layer 120 has the opening 120OP exposing the central portion of the first electrode 210. The pixel-defining layer 120 may be disposed on the via insulating layer 110. It is shown in the cross-sectional view of FIG. 5 that the first pixel-defining layer 121 is disposed on the first electrode 210 in the second direction (e.g., the x direction). However, the second pixel-defining layer 122 may also be disposed on the first electrode 210 to cover a portion of the first electrode 210.

The first pixel-defining layer 121 may be disposed on the via insulating layer 110. In an embodiment, the first pixel-defining layer 121 may be disposed in the groove 110G in the via insulating layer 110. As shown in FIG. 5, the first portion 121a of the first pixel-defining layer 121 disposed between the first electrodes 210 may be disposed in the groove 110G in the via insulating layer 110. As shown in FIG. 6, the second portion 121b of the first pixel-defining layer 121 disposed between the second pixel-defining layers 122 may be disposed in the groove 110G in the via insulating layer 110. That is, in the illustrated embodiment, both the first portion 121a and the second portion 121b of the first pixel-defining layer 121 may be disposed in the groove 110G in the via insulating layer 110.

Accordingly, as shown in FIG. 5, a distance Da between the upper surface of the substrate 100 and the lower surface of the first portion 121a of the first pixel-defining layer 121 may be less than a distance Db between the upper surface of the substrate 100 and the lower surface of the first electrode 210. Accordingly, as shown in FIG. 6, a distance Dc between the upper surface of the substrate 100 and the lower surface of the second portion 121b of the first pixel-defining layer 121 may be less than a distance Dd between the upper surface of the substrate 100 and the lower surface of the second pixel-defining layer 122. In an embodiment, the distance Da between the upper surface of the substrate 100 and the lower surface of the first portion 121a of the first pixel-defining layer 121 may be substantially equal to the distance Dc between the upper surface of the substrate 100 and the lower surface of the second portion 121b of the first pixel-defining layer 121, but the present disclosure is not limited thereto.

In an embodiment, as shown in FIG. 7, the first pixel-defining layer 121 may have a substantially uniform thickness T1 in the first direction (e.g., the y direction). That is, the thickness of the first portion 121a of the first pixel-defining layer 121 may be substantially equal to the thickness of the second portion 121b.

In an embodiment, as shown in FIG. 6, a thickness T1 of the first pixel-defining layer 121 may be greater than a thickness T2 of the second pixel-defining layer 122. In another embodiment, the thickness T1 of the first pixel-defining layer 121 may be substantially equal to the thickness T2 of the second pixel-defining layer 122. Although it is shown in FIG. 6 that the height of the upper surface of the first pixel-defining layer 121 is greater than the height of the upper surface of the second pixel-defining layer 122, the present disclosure is not limited thereto.

Where the first pixel-defining layer 121 overlaps the second pixel-defining layer 122, the thickness of a portion of the first pixel-defining layer 121 that overlaps the second pixel-defining layer 122 is reduced, and a repellent characteristic of the first pixel-defining layer 121 is reduced. In an embodiment, because the first pixel-defining layer 121 does not overlap the second pixel-defining layer 122, the thickness T1 of the first pixel-defining layer 121 may be formed in a range in which a repellent characteristic is not reduced or lost.

In addition, in an embodiment, the groove 110G in the via insulating layer 110 has a line shape over a region thereof overlapping the first pixel-defining layer 121, and thus, the thickness T1 of the first pixel-defining layer 121 may be thicker. Accordingly, the spreadability of ink for forming the intermediate layer 220, described below, may be improved by increasing a repellent characteristic of the first pixel-defining layer 121.

The intermediate layer 220 may be disposed on the first electrode 210. The intermediate layer 220 may be disposed on the first electrode 210. The intermediate layer 220 may include, for example, an organic emission layer. The organic emission layer may include an organic material including a fluorescent or phosphorous material for emitting red, green, blue, or white light. The organic emission layer may include a low molecular weight organic material or a polymer organic material. The intermediate layer 220 may be formed by an inkjet process. As an example, the emission layer of the intermediate layer 220 may be formed by an inkjet process.

The intermediate layer 220 may include a common layer disposed under and/or on the organic emission layer. The common layer may include a hole transport layer (HTL), a hole injection layer (HIL), an electron transport layer (ETL), and/or an electron injection layer (EIL), and similar to the second electrode 230, the common layer may cover the plurality of first electrodes 210. In other words, the second electrode 230 and the common layer may share (or may be common to) a plurality of light-emitting diodes LED. The common layer may be formed by an inkjet process.

The second electrode 230 may be disposed on the intermediate layer 220. The second electrode 230 may entirely cover the display area DA of the substrate 100. The second electrode 230 may be a light-transmissive electrode or a reflective electrode. The second electrode 230 may include a conductive material having a low work function. As an example, the second electrode 230 may include a (semi) transparent layer including silver (Ag), magnesium (Mg), aluminum (AI), platinum (Pt), palladium (Pd), gold (Au), nickel (Ni), neodymium (Nd), iridium (Ir), chrome (Cr), or an alloy thereof. In some embodiments, the second electrode 230 may further include a layer on a (semi) transparent layer including ITO, IZO, ZnO, or In₂O₃.

The light-emitting diode LED may be covered by an encapsulation layer including at least one organic encapsulation layer and at least one inorganic encapsulation layer. In an embodiment, at least one inorganic encapsulation layer and at least one organic encapsulation layer may be alternately stacked. The inorganic encapsulation layer may include at least one inorganic material from among aluminum oxide (e.g., Al₂O₃), titanium oxide (e.g., TiO₂), tantalum oxide (e.g., Ta₂O₅), zinc oxide (ZnOₓ), silicon oxide (e.g., SiO₂), silicon nitride (SiNₓ), and silicon oxynitride (SiON). The organic encapsulation layer may include a polymer-based material. The polymer-based material may include an acryl-based resin, an epoxy-based resin, polyimide, and polyethylene. In an embodiment, the organic encapsulation layer may include acrylate.

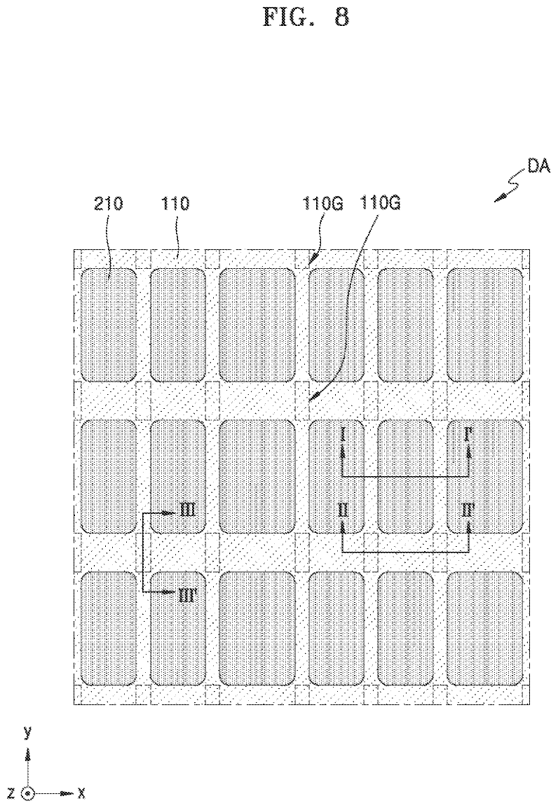

FIG. 8 is a schematic plan view of a portion of a display area DA of the display apparatus according to another embodiment. FIG. 8 is a plan view of the via insulating layer 110 of a region corresponding to that shown in FIG. 4 according to another embodiment. Hereinafter, descriptions that are the same as those given above with reference to FIGS. 3 and 4 will be omitted and the description will focus on the shape of the groove 110G in the via insulating layer 110.

Referring to FIGS. 3 and 4, each of the grooves 110G in the via insulating layer 110 may overlap a portion of one first pixel-defining layer 121. In an embodiment, each of the grooves 110G in the via insulating layer 110 may be formed in a pattern shape instead of a line shape extending in one direction. As an example, the grooves 110G in the via insulating layer 110 may be spaced apart from each other in the first direction (e.g., the y direction) and the second direction (e.g., the x direction). In an embodiment, the groove 110G in the via insulating layer 110 may overlap the second portion 121b of the first pixel-defining layer 121 and may not overlap the first portion 121a of the first pixel-defining layer 121. In this embodiment, the groove 110G in the via insulating layer 110 may not overlap the first electrodes 210.

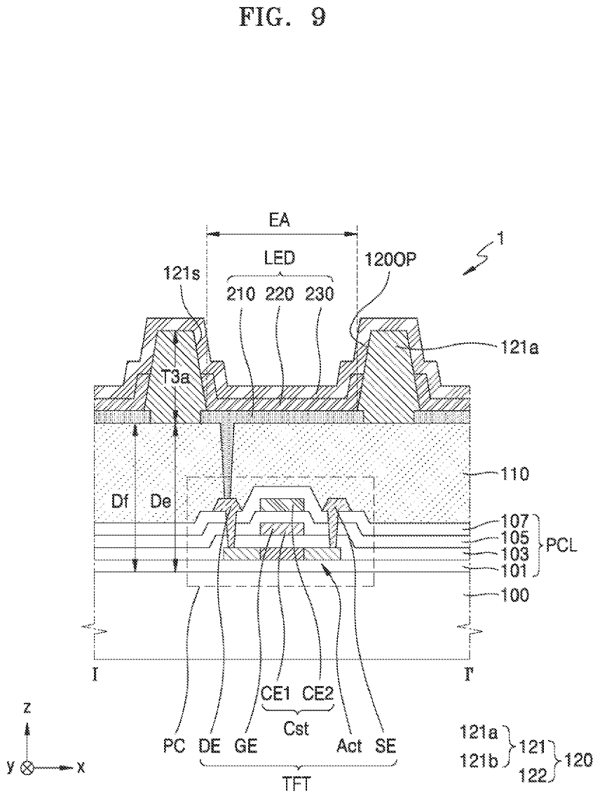

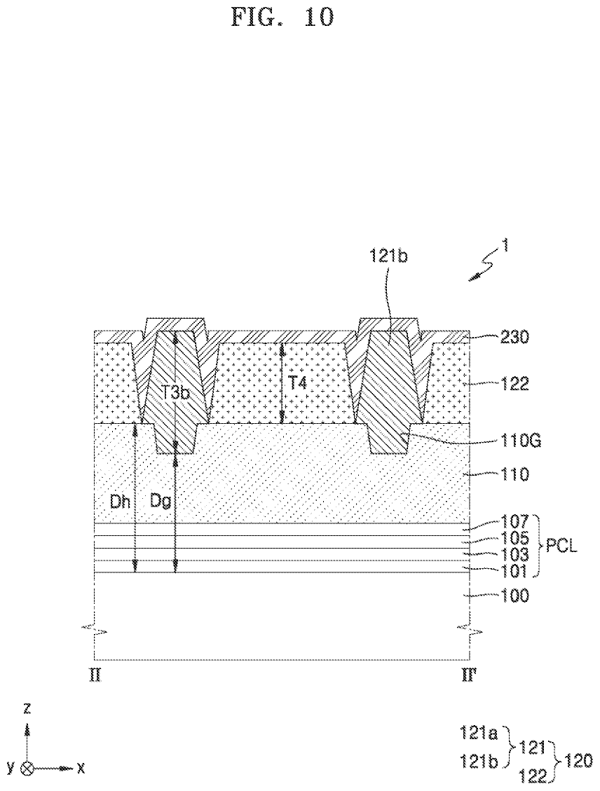

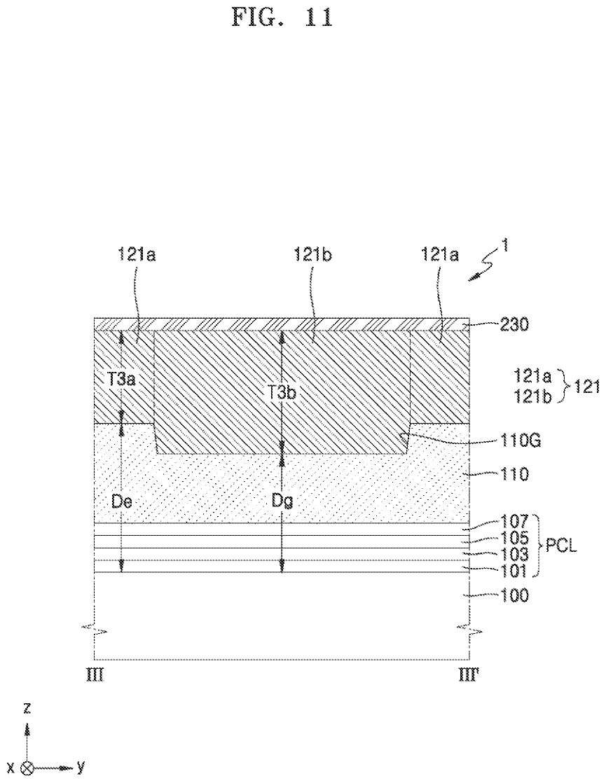

FIGS. 9 to 11 are schematic cross-sectional views of the display apparatus shown in FIG. 8. FIG. 9 is a schematic cross-sectional view of the display apparatus shown in FIG. 8 taken along the line I-I′ in FIG. 8. FIG. 10 is a schematic cross-sectional view of the display apparatus shown in FIG. 8 taken along the line II-II′ in FIG. 8. FIG. 11 is a schematic cross-sectional view of the display apparatus shown in FIG. 8 taken along line III-III′ in FIG. 8. Hereinafter, descriptions that are the same as those given above with reference to FIGS. 5 to 7 will be omitted and the description will focus on different aspects.

Referring to FIGS. 9 to 11, the via insulating layer 110 may have the groove 110G in a portion of a region overlapping the first pixel-defining layer 121. In an embodiment, the via insulating layer 110 may not have the groove 110G in a region overlapping the first portion 121a of the first pixel-defining layer 121 and may have the groove 110G in a region overlapping the second portion 121b of the first pixel-defining layer 121.

In an embodiment, a portion of the first pixel-defining layer 121 may be disposed on the via insulating layer 110 at where the groove 110G is not formed, and the rest of the first pixel-defining layer 121 may be disposed in the groove 110G. As shown in FIGS. 9 and 11, the first portion 121a of the first pixel-defining layer 121 disposed between the first electrodes 210 may be disposed on the via insulating layer 110 at where the groove 110G is not formed. As shown in FIGS. 10 and 11, the second portion 121b of the first pixel-defining layer 121 disposed between the second pixel-defining layers 122 may be disposed in the groove 110G in the via insulating layer 110. That is, in an embodiment, the first portion 121a of the first pixel-defining layer 121 may not be disposed in the groove 110G in the via insulating layer 110, and the second portion 121b may be disposed in the groove 110G in the via insulating layer 110. The first portion 121a of the first pixel-defining layer 121 may not overlap (e.g., may be offset from) the groove 110G in the via insulating layer 110.

Accordingly, as shown in FIG. 9, a distance De between the upper surface of the substrate 100 and the lower surface of the first portion 121a of the first pixel-defining layer 121 may be substantially equal to a distance Df between the upper surface of the substrate 100 and the lower surface of the first electrode 210. Accordingly, as shown in FIG. 10, a distance Dg between the upper surface of the substrate 100 and the lower surface of the second portion 121b of the first pixel-defining layer 121 may be less than a distance Dh between the upper surface of the substrate 100 and the lower surface of the second pixel-defining layer 122. In an embodiment, as shown in FIG. 11, a distance De between the upper surface of the substrate 100 and the lower surface of the first portion 121a of the first pixel-defining layer 121 may be greater than a distance Dg between the upper surface of the substrate 100 and the lower surface of the second portion 121b of the first pixel-defining layer 121.

In an embodiment, as shown in FIG. 11, the first pixel-defining layer 121 may have portions having different thicknesses in the first direction (e.g., the y direction). That is, the thickness of the first pixel-defining layers 121 may not be uniform in the first direction. A thickness T3b of the second portion 121b of the first pixel-defining layer 121 may be greater than a thickness T3a of the first portion 121a of the first pixel-defining layer 121.

In an embodiment, the thickness of the first pixel-defining layer 121 may be substantially equal to or greater than the thickness of the second pixel-defining layer 122. As an example, the thickness T3a (see, e.g., FIG. 9) of the first portion 121a of the first pixel-defining layer 121 may be substantially equal to or greater than a thickness T4 (see, e.g., FIG. 10) of the second pixel-defining layer 122. As shown in FIG. 10, a thickness T3b of the second portion 121b of the first pixel-defining layer 121 may be greater than the thickness T4 of the second pixel-defining layer 122.

In an embodiment, the groove 110G in the via insulating layer 110 is formed in a region overlapping a portion of the first pixel-defining layer 121 disposed between the second pixel-defining layers 122, and the thickness of the first pixel-defining layer 121 is not reduced in a region adjacent to the second pixel-defining layer 122. Thus, a loss in a repellent characteristic of the first pixel-defining layer 121 may be prevented.

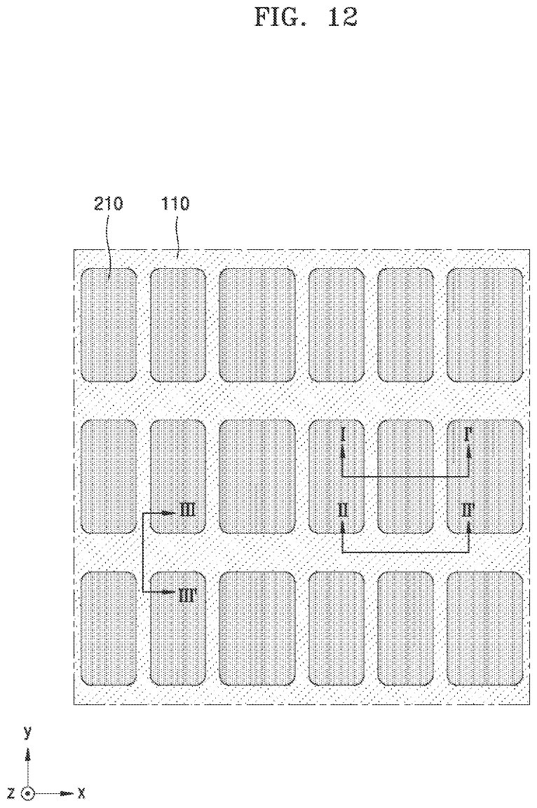

FIG. 12 is a schematic plan view of a portion of a display area of a display apparatus according to another embodiment. FIG. 12 is a plan view of the via insulating layer 110 in a region corresponding that shown in FIG. 4 according to another embodiment.

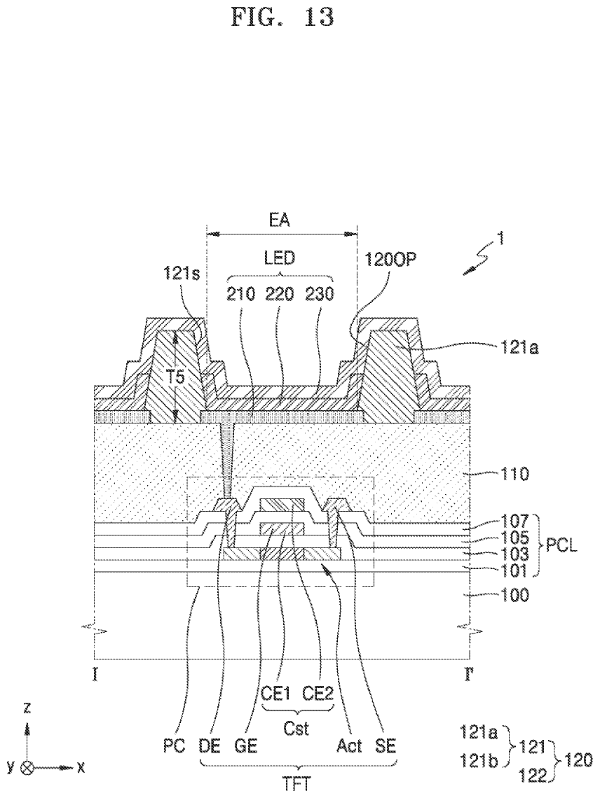

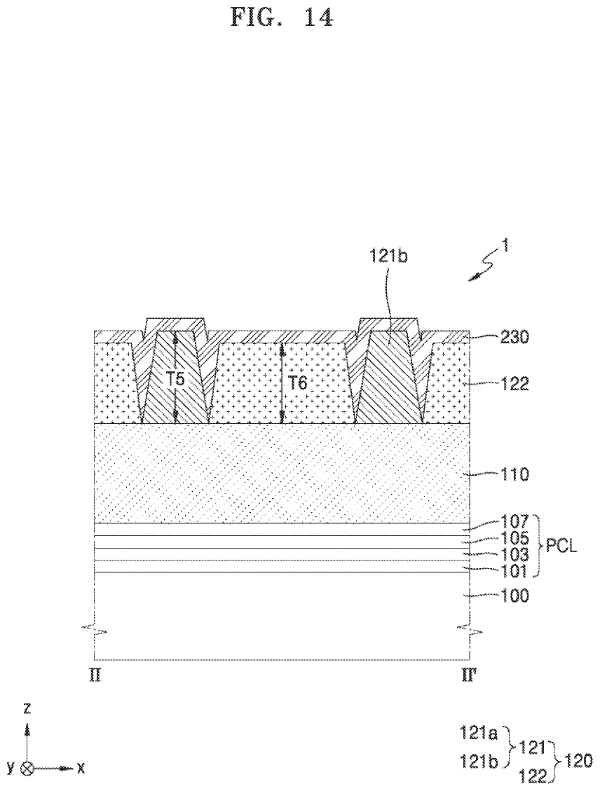

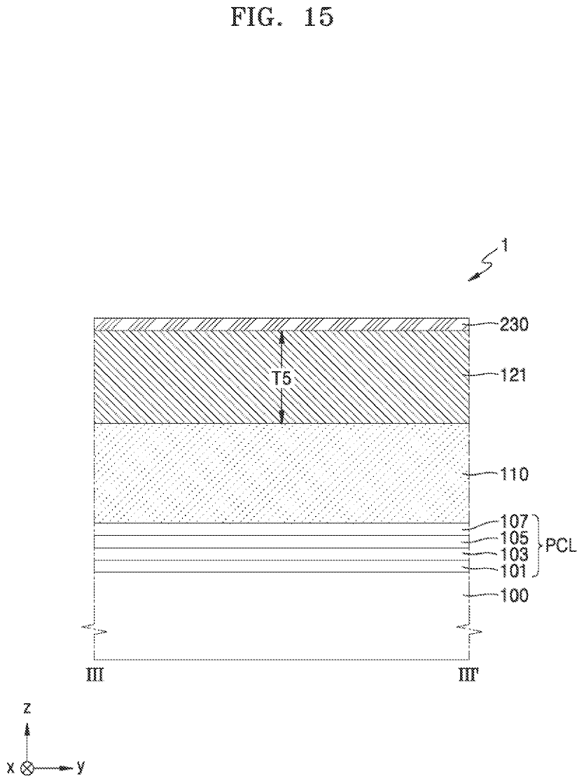

FIGS. 13 to 15 are schematic cross-sectional views of the display apparatus shown in FIG. 12. FIG. 13 is a schematic cross-sectional view of the display apparatus shown in FIG. 12 taken along the line I-I′ in FIG. 12. FIG. 14 is a schematic cross-sectional view of the display apparatus shown in FIG. 12 taken along the line II-II′ in FIG. 12. FIG. 15 is a schematic cross-sectional view of the display apparatus shown in FIG. 12 taken along the line III-III′ in FIG. 12. Hereinafter, descriptions that are the same as those given above with reference to FIGS. 3 to 7 will be omitted and the description will primarily focus on different aspects.

Referring to FIGS. 3 and 12 to 15, the via insulating layer 110 may not have the groove 110G. The via insulating layer 110 may have an upper surface at the substantially same height over an entire region thereof. As an example, a distance between the upper surface of the substrate 100 and the lower surface of the first portion of the first pixel-defining layer 121 may be substantially equal to a distance between the upper surface of the substrate 100 and the lower surface of the first electrode 210. As an example, a distance between the upper surface of the substrate 100 and the lower surface of the second portion 121b of the first pixel-defining layer 121 may be substantially equal to a distance between the upper surface of the substrate 100 and the lower surface of the second pixel-defining layer 122. As an example, a distance between the upper surface of the substrate 100 and the first portion 121a of the first pixel-defining layer 121 may be substantially equal to a distance between the upper surface of the substrate 100 and the second portion 121b of the first pixel-defining layer 121.

In an embodiment, as shown in FIG. 15, the first pixel-defining layer 121 may have a substantially uniform thickness T5 in the first direction (e.g., the y direction). That is, the thickness of the first portion 121a of the first pixel-defining layer 121 may be substantially equal to the thickness of the second portion 121b.

In an embodiment, as shown in FIG. 14, although a thickness T5 of the first pixel-defining layer 121 may be greater than a thickness T6 of the second pixel-defining layer 122, the present disclosure is not limited thereto. As an example, the thickness T5 of the first pixel-defining layer 121 may be substantially equal to the thickness T6 of the second pixel-defining layer 122. Although it is shown in FIG. 14 that the height of the upper surface of the first pixel-defining layer 121 is greater than the height of the upper surface of the second pixel-defining layer 122 above the upper surface of via insulating layer 110, the present disclosure is not limited thereto.

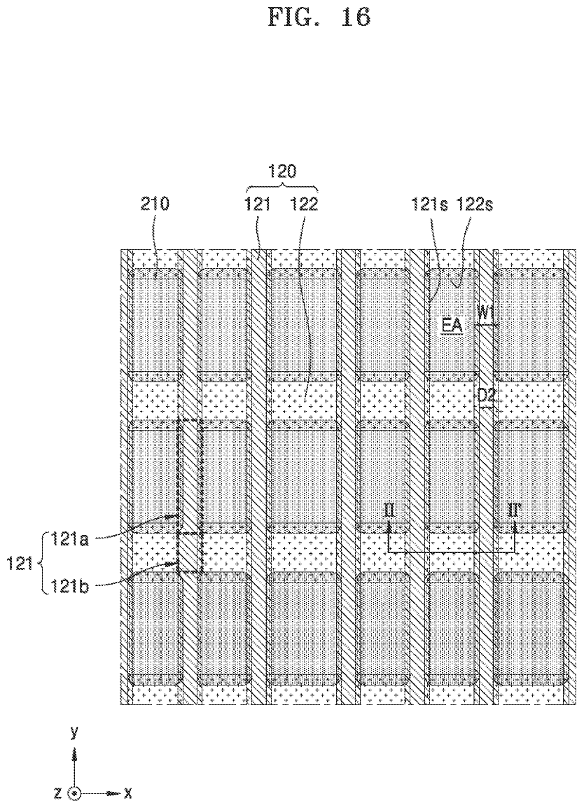

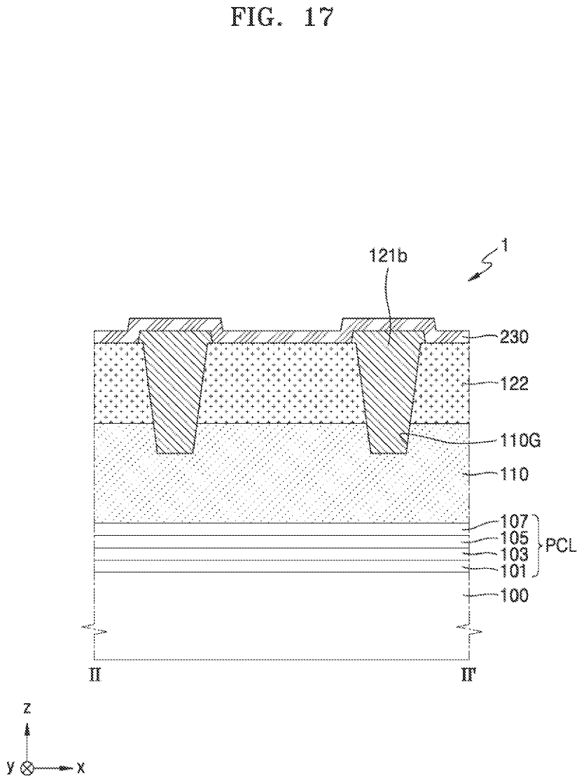

FIG. 16 is a schematic plan view of a portion of a display apparatus according to another embodiment. FIG. 16 shows a plan view of the pixel-defining layer 120 according to another embodiment in a region corresponding to that shown in FIG. 3. FIG. 17 is a schematic cross-sectional view of the display apparatus shown in FIG. 16. FIG. 17 is a schematic cross-sectional view of the display apparatus shown in FIG. 16 taken along the line II-II′ in FIG. 16. Hereinafter, descriptions that are the same as those given above with reference to FIGS. 3 to 7 will be omitted and the description will primarily focus on different aspects.

Referring to FIGS. 16 and 17, the width W1 in the second direction (e.g., the x direction) of the first pixel-defining layer 121 disposed between a pair of second pixel-defining layers 122 adjacent to each other from among the first pixel-defining layers 121 may be greater than a distance D2 between the pair of second pixel-defining layers 122 adjacent to each other. A portion of the first pixel-defining layer 121 may cover a portion of the edge of the second pixel-defining layer 122. In other words, a portion of the first pixel-defining layer 121 may overlap a portion of the edge of the second pixel-defining layer 122. However, even in this embodiment, a portion of the second portion 121b of the first pixel-defining layer 121 disposed between the first pixel-defining layers 121 adjacent to each other may overlap the second pixel-defining layer 122, and the rest of the second portion 121b of the first pixel-defining layer 121 may not overlap the second pixel-defining layer 122.

In an embodiment, because the first pixel-defining layer 121 has at least a portion not overlapping in a region adjacent to the second pixel-defining layer 122, the thickness of the first pixel-defining layer 121 may be formed in a range in which a repellant characteristic is not reduced or lost.

Although it is shown in FIG. 17 that the via insulating layer 110 has the groove 110G, this is an example, and the present disclosure is not limited thereto. As an example, in the embodiment shown in FIGS. 16 and 17, the shape of the via insulating layer 110 according to the embodiment shown in FIG. 4, the embodiment shown in FIG. 8, or the embodiment shown in FIG. 12 may be used.

According to embodiments of the present disclosure, a hydrophilic pixel-defining layer is formed in a pattern that does not cross a repellant pixel-defining layer having a line shape extending in one direction, and thus, the reliability of the display apparatus may be improved by maintaining a repellant characteristic of the pixel-defining layer. However, the scope of the present disclosure is not limited by these aspects and features.

It should be understood that the embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display apparatus comprising:
a substrate;
a pixel-circuit layer on the substrate and comprising a pixel circuit;
a via insulating layer on the pixel-circuit layer;
a first electrode on the via insulating layer;
a pixel-defining layer on the first electrode and exposing a portion of the first electrode, the pixel-defining layer comprising:
a plurality of first pixel-defining layers extending in a first direction and adjacent to each other in a second direction crossing the first direction; and
a plurality of second pixel-defining layers respectively between adjacent ones of the first pixel-defining layers; and
a second electrode on the first electrode,
wherein the second pixel-defining layers are spaced apart from each other, and
wherein the via insulating layer has a groove in at least a portion of a region at where the first pixel-defining layers overlaps the via insulating layer.

2. The display apparatus of claim 1, wherein the first pixel-defining layers have a repellent characteristic, and the second pixel-defining layers have a hydrophilic characteristic.

3. The display apparatus of claim 1, wherein the first electrode is provided in plurality,
wherein each of the first pixel-defining layers has a first portion between the first electrodes and a second portion outside the first portion and between adjacent ones of the second pixel-defining layers, and
wherein the groove in the via insulating layer overlaps the second portion of each of the first pixel-defining layers.

4. The display apparatus of claim 3, wherein the groove in the via insulating layer extends in the first direction and overlaps the first portion and the second portion of each of the first pixel-defining layers.

5. The display apparatus of claim 3, wherein at least a portion of the second portion of each of the first pixel-defining layers does not overlap the second pixel-defining layers.

6. The display apparatus of claim 1, wherein a thickness of each of the first pixel-defining layers is greater than a thickness of each of the second pixel-defining layers.

7. The display apparatus of claim 1, wherein a width of the first pixel-defining layer in the second direction between an adjacent pair of the second pixel-defining layers from among the first pixel-defining layers is equal to a distance between the adjacent pair of second pixel-defining layers.

8. The display apparatus of claim 1, wherein a width of the first pixel-defining layer in the second direction between an adjacent pair of the second pixel-defining layers from among the first pixel-defining layers is greater than a distance between the adjacent pair of second pixel-defining layers.

9. The display apparatus of claim 1, wherein the first electrode is provided in plurality, and
wherein the pixel-defining layer and the first electrodes cover an entire upper surface of the via insulating layer.

10. The display apparatus of claim 1, wherein the groove in the via insulating layer does not overlap the first electrode.

11. A display apparatus comprising:
a substrate;
a pixel-circuit layer on the substrate and comprising a pixel circuit;
a first electrode on the pixel-circuit layer;
a pixel-defining layer on the first electrode and exposing a portion of the first electrode, the pixel-defining layer comprising:
a plurality of first pixel-defining layers extending in a first direction and adjacent to each other in a second direction crossing the first direction; and
a plurality of second pixel-defining layers respectively between adjacent ones of the first pixel-defining layers; and
a second electrode on the first electrode,
wherein the second pixel-defining layers are spaced apart from each other, and
wherein a width of the first pixel-defining layer in the second direction between an adjacent pair of second pixel-defining layers from among the first pixel-defining layers is equal to or greater than a distance between the adjacent pair of second pixel-defining layers.

12. The display apparatus of claim 11, wherein the first pixel-defining layers comprises a repellent material, and the second pixel-defining layers comprises a hydrophilic material.

13. The display apparatus of claim 11, wherein the first pixel-defining layers each has a uniform thickness in the first direction.

14. The display apparatus of claim 11, wherein the first electrode is provided in plurality,
wherein each of the first pixel-defining layers has a first portion between adjacent ones of the first electrodes and a second portion outside the first portion and between adjacent ones of the second pixel-defining layers, and
wherein a thickness of the second portion of each of the first pixel-defining layers is greater than a thickness of the first portion.

15. The display apparatus of claim 11, further comprising a via insulating layer between the pixel-circuit layer and the first electrode,
wherein the via insulating layer has grooves in at least a portion of a region overlapping the first pixel-defining layers.

16. The display apparatus of claim 15, wherein the grooves extend in the first direction and are adjacent to each other in the second direction.

17. The display apparatus of claim 15, wherein the first electrode is provided in plurality,
wherein each of the first pixel-defining layers has a first portion arranged between adjacent ones of the first electrodes and a second portion arranged outside the first portion and arranged between adjacent ones of the second pixel-defining layers, and
wherein the grooves overlap the second portion of the second pixel-defining layers.

18. The display apparatus of claim 15, wherein the grooves in the via insulating layer do not overlap the first electrode.

19. The display apparatus of claim 11, wherein a thickness of each of the first pixel-defining layers is equal to or greater than a thickness of each of the second pixel-defining layers.

20. The display apparatus of claim 11, wherein the first electrode is provided in plurality,
wherein each of the first pixel-defining layers has a first portion between adjacent ones of the first electrodes and a second portion outside the first portion and between adjacent ones of the second pixel-defining layers, and
wherein at least a portion of the second portion of each of the first pixel-defining layers does not overlap the second pixel-defining layers.
